(19) United States
(12) Patent Application Publication
(10) Pub. No.: US 2025/0212543 A1
(43) Pub. Date: Jun. 26, 2025

(54) LIGHT DETECTION DEVICE AND ELECTRONIC APPARATUS

(71) Applicant: SONY SEMICONDUCTOR SOLUTIONS CORPORATION, Kanagawa (JP)

(72) Inventors: Kaito YOKOCHI, Kanagawa (JP); Takayuki OGASAHARA, Kanagawa (JP); Seiki TAKAHASHI, Kanagawa (JP); Koji MIYATA, Kanagawa (JP); Hiroaki TAKASE, Kanagawa (JP)

(73) Assignee: SONY SEMICONDUCTOR SOLUTIONS CORPORATION, Kanagawa (JP)

(21) Appl. No.: 18/847,754

(22) PCT Filed: Mar. 28, 2023
(86) PCT No.: PCT/JP2023/012710

§ 371 Date: Sep. 17, 2024

(30) Foreign Application Priority Data
Apr. 4, 2022 (JP) 2022-062668

(51) Int. Cl. H10F 39/00; H10F 39/18

(52) U.S. Cl. CPC H10F 39/8063; H10F 39/182; H10F 39/8053

(57) ABSTRACT

A light detection device comprises a pixel array having a plurality of pixels. At least one of the plurality of pixels includes a photoelectric conversion region configured to perform photoelectric conversion, a light guide region including first nanostructures that guide light to the photoelectric conversion region, and a refraction structure arranged between the light guide region and the photoelectric conversion region and that causes light exiting the light guide region to refract in a refraction direction.

### CROSS REFERENCE TO RELATED APPLICATIONS

This application claims the benefit of Japanese Priority Patent Application JP2022-062668 filed Apr. 4, 2022, the entire contents of which are incorporated herein by reference.

### TECHNICAL FIELD

The present disclosure relates to a light detection device and an electronic apparatus.

### BACKGROUND ART

In general, image sensors have on-chip lenses arranged on the side of the light incident surfaces of the photodiodes of respective pixels. With the provision of the on-chip lenses, it is possible to form an image of incident light on the light receiving surface of a photoelectric conversion region. Meanwhile, a technology in which fine structures are arranged on the side of the light incident surfaces of photodiodes instead of on-chip lenses to control the propagating direction of light incident on the fine structures has been proposed (see PTL 1).

### CITATION LIST

### Patent Literature

PTL 1: JP 2021-69119A

### SUMMARY

### Technical Problem

However, light contains various wavelength components. Therefore, the propagating direction of light having passed through the fine structures changes according to the wavelength of the light, and an image forming position also varies according to the wavelength. Accordingly, a beam diameter on the light receiving surface of a photo-electric conversion region is made different depending on the wavelength, which causes a reduction in image quality.

Further, when light from an oblique direction is incident on the fine structures, there is a possibility that the light having passed through the fine structures overlaps each other on the light receiving surface of the photoelectric conversion region to cause color mixture or is incident on adjacent pixel regions to cause shading.

In view of this, the present disclosure provides a light detection device capable of suppressing color mixture and shading when fine structures are used.

### Solution to Problem

In order to solve the above problem, the present disclosure provides a light detection device including: a photoelectric conversion region having a plurality of pixels; a light control region that is arranged on a light incident direction side with respect to the photoelectric conversion region and has a fine structure to control a propagating direction of incident light; and a refraction direction adjustment member that is arranged between the light control region and the photoelectric conversion region and adjusts a refraction direction of light emitted from the light control region.

The present disclosure provides a light detection device including:
a photoelectric conversion region having a plurality of pixels;
a light control region that is arranged on a light incident direction side with respect to the photoelectric conversion region and has a fine structure to control a propagating direction of incident light;
a color filter region that is arranged between the light control region and the photo-electric conversion region; and
a refraction direction adjustment member that is arranged between the light control region and the color filter region and adjusts a refraction direction of light emitted from the light control region.

The refraction direction adjustment member may have, for each of the plurality of pixels, a laminated body that adjusts a refraction direction according to a wavelength of incident light.

The laminated body of the refraction direction adjustment member may include two or more laminated bodies that correspond to light of two or more wavelengths incident on the light control region, and
the two or more laminated bodies may have refractive indexes different from each other.

The photoelectric conversion region may have a plurality of color pixels for each of the plurality of pixels, and
the refraction direction adjustment member may adjust the refraction direction of the light emitted from the light control region so as to correspond to each of the plurality of color pixels.

The light control region may have a pixel control region having the fine structure for each of the plurality of color pixels, and
the refraction direction adjustment member may adjust a refraction direction of light emitted from the pixel control region corresponding to at least one color pixel among the plurality of pixel control regions corresponding to the plurality of color pixels.

The refraction direction adjustment member may make refraction directions of light emitted from two or more of the pixel control regions among the plurality of pixel control regions corresponding to the plurality of color pixels different from each other, the two or more of the pixel control regions corresponding to the two or more color pixels of different colors.

The refraction direction adjustment member may have two or more laminated bodies that are arranged in regions on which the light emitted from the two or more pixel control regions is incident, each of the two or more laminated bodies including two or more light transmission layers having refractive indexes different from each other, and
the refractive indexes of one or more of the light transmission layers provided in each of the two or more laminated bodies may be different from each other.

Each of the two or more laminated bodies may have
a first light transmission layer having a same refractive index, and
a second light transmission layer that has a different refractive index and is laminated on the first light transmission layer.

The refraction direction adjustment member may emit light without changing a re-fraction direction of the light emitted from the pixel control region corresponding to a color pixel of a specific color among the plurality of color pixels and separately adjusts refraction directions of light emitted from the pixel control regions corresponding to color pixels of colors other than the specific color for each of the colors.

The refraction direction adjustment member may adjust a refraction direction of light emitted from at least a part of the pixel control regions so that focal distances of light emitted from the plurality of pixel control regions corresponding to the plurality of color pixels become uniform.

The refraction direction adjustment member may adjust a refraction direction of light emitted from at least a part of the pixel control regions so that beam diameters on the photoelectric conversion region of the light emitted from the plurality of pixel control regions corresponding to the plurality of color pixels become uniform.

The refraction direction adjustment member may contain a material having a refractive index n adjusted so that a focal position f expressed by f=φ×D×n/(c×λ) becomes uniform at all wavelengths λ when a wavelength of light emitted from the light control region is represented by λ, a refractive index of the refraction direction adjustment member is represented by n, a beam diameter on a light incident surface of the light control region is represented by D, a beam diameter on a light receiving surface of the photoelectric conversion region is represented by φ, a focal position of light emitted from the refraction direction adjustment member is represented by f, and a coefficient composed of a prescribed real number is represented by c.

The refraction direction adjustment member may have a separate fine structure having a configuration different from a configuration of the fine structure of the light control region, and
the separate fine structure may adjust a refraction direction of light emitted from at least a part of the pixel control regions and perform pupil correction so that focal distances of light emitted from the plurality of pixel control regions corresponding to the plurality of color pixels become uniform.

The refraction direction adjustment member may have a laminated body in which two or more light transmission layers having refractive indexes different from each other are laminated and the separate fine structure,
the laminated body may be arranged at a place at which no pupil correction is required, and
the separate fine structure may be arranged at a place at which pupil correction is required.

The plurality of color pixels may have red, green, and blue color pixels, and
the refraction direction adjustment member may have
a first region in which light incident on the red color pixels is refracted,
a second region in which light incident on the green color pixels is refracted, and
a third region in which light incident on the blue color pixels is refracted, make a refractive index of the second region larger than a refractive index of the first region, and
make a refractive index of the third region larger than the refractive index of the second region.

The present disclosure provides an electronic apparatus including:
a light detection device that outputs a light-detected pixel signal; and
a signal processing section that performs signal processing of the pixel signal, wherein
the light detection device includes
a photoelectric conversion region having a plurality of pixels,
a light control region that is arranged on a light incident direction side with respect to the photoelectric conversion region and has a fine structure to control a propagating direction of incident light, and
a refraction direction adjustment member that is arranged between the light control region and the photoelectric conversion region and adjusts a refraction direction of light emitted from the light control region. The present disclosure further provides a light detection device comprising a pixel array having a plurality of pixels, at least one of the plurality of pixels including a photoelectric conversion region configured to perform photoelectric conversion, a light guide region including first nanostructures that guide light to the photoelectric conversion region, a refraction structure arranged between the light guide region and the photoelectric conversion region and that causes light exiting the light guide region to refract in a refraction direction. The present disclosure may comprise an electronic apparatus including a light detection device. At least embodiment of the present disclosure is directed to a light detection device comprising a plurality of pixels, each of the plurality of pixels including a photoelectric conversion region configured to perform photoelectric conversion, a light guide region including first nanostructures that guide light to the photoelectric conversion region, and a refraction structure that causes light exiting the light guide region to refract in a refraction direction.

### BRIEF DESCRIPTION OF DRAWINGS

FIG. 1 is a block diagram showing the schematic configuration of a light detection device according to an embodiment of the present disclosure.

FIG. 2 is a diagram for describing the principle of a fine structure.

FIG. 3 is a schematic cross-sectional diagram of a light detection device 1 according to the present embodiment.

FIG. 4 is a diagram for describing a color splitter.

FIG. 5A is a plane diagram schematically showing a state in which respective pixel control regions corresponding to respective color pixels inside the color splitter take in light from peripheries.

FIG. 5B is a plane diagram schematically showing a state in which respective pixel control regions corresponding to respective color pixels inside the color splitter take in light from peripheries.

FIG. 5C is a plane diagram schematically showing a state in which respective pixel control regions corresponding to respective color pixels inside the color splitter take in light from peripheries.

FIG. 6 is a diagram for describing the focal distance of light having passed through the color splitter.

FIG. 7 is a diagram showing focal distances, light propagating directions, and color mixture amounts with respect to three wavelengths.

FIG. 8 is a diagram for describing the optical function of a refraction direction adjustment member according to the present embodiment.

FIG. 9A is a cross-sectional diagram of a light detection device in which an insulating layer is provided instead of the refraction direction adjustment member.

FIG. 9B is a cross-sectional diagram of the light detection device in which the refraction direction adjustment member is provided.

FIG. 9C is a plane diagram of the color filter region of FIGS. 9A and 9B.

FIG. 9D is a plane diagram of the light control region of FIGS. 9A and 9B.

FIG. 10 is a diagram showing beam diameters on the light receiving surface of a photoelectric conversion region in the light detection devices.

FIG. 11A is a plane diagram for describing the pitch diameter, the pitch interval, and the gap interval of pillar parts.

FIG. 11B is a cross-sectional diagram for describing the height of the pillar parts.

FIG. 12A is a plane diagram showing a first example of the fine structures inside the color splitter.

FIG. 12B is a plane diagram showing a second example of the fine structures inside the color splitter.

FIG. 12C is a plane diagram showing a third example of the fine structures inside the color splitter.

FIG. 13 is a cross-sectional diagram showing a modified example of the refraction direction adjustment member shown in FIG. 8.

FIG. 14 is a block diagram showing a schematic configuration example of a vehicle control system.

FIG. 15 is a diagram showing an example of the installation positions of a vehicle outside information detection section and an imaging section.

### DESCRIPTION OF EMBODIMENTS

Hereinafter, embodiments of a light detection device and an electronic apparatus will be described with reference to the drawings. The principal constituting portions of the light detection device and the electronic apparatus will be particularly described below, but the light detection device and the electronic apparatus can have constituting portions or functions not shown or described. The following description does not exclude the constituting portions or functions not shown or described.

### (Schematic Configuration of Imaging Device)

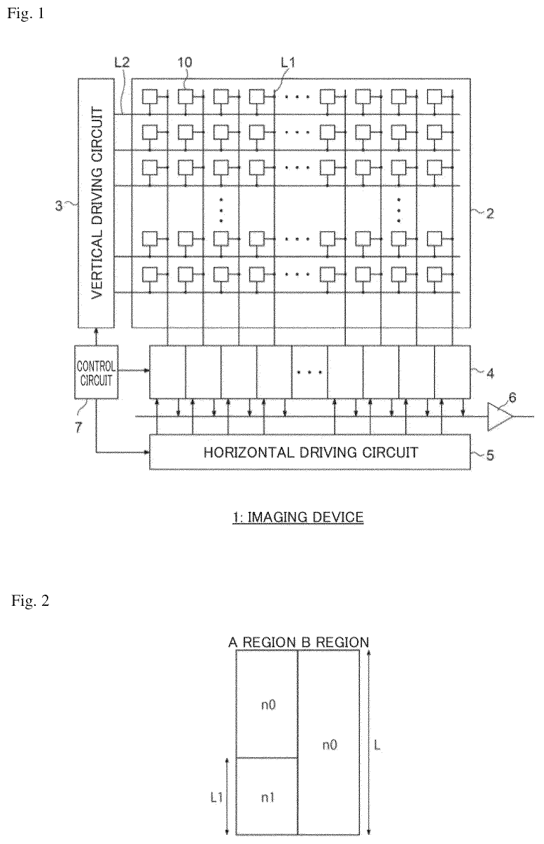

FIG. 1 is a block diagram showing the schematic configuration of a light detection device 1 according to an embodiment of the present disclosure. The light detection device 1 of FIG. 1 shows the schematic configuration of an image sensor, that is, an imaging device. Note that the light detection device 1 according to the present embodiment is also applicable to a device including a light detection function other than an image sensor, for example, a ToF (Time of Flight) device, a photo count device, or the like.

The light detection device 1 of FIG. 1 includes a pixel array unit 2, a vertical driving circuit 3, a column signal processing circuit 4, a horizontal driving circuit 5, an output circuit 6, and a control circuit 7.

The pixel array unit 2 has a plurality of pixel units 10 arranged in a row direction and a column direction, a plurality of signal lines L1 extending in the column direction, and a plurality of row selection lines L2 extending in the row direction. Each pixel unit 10 may include one or more pixels. Although omitted in FIG. 1, the pixel units 10 have a photoelectric conversion part and a readout circuit that reads out pixel signals corresponding to photoelectrically-converted charges to the signal lines L1. The pixel array unit 2 is a laminated body in which a photoelectric conversion region in which the photoelectric conversion parts are arranged in a two-dimensional direction and a readout circuit region in which the readout circuits are arranged in the two-dimensional direction are laminated.

The vertical driving circuit 3 drives the plurality of row selection lines L2. Specifically, the vertical driving circuit 3 line-sequentially supplies driving signals to the plurality of row selection lines L2 and line-sequentially selects the respective row selection lines L2.

The plurality of signal lines L1 extending in the column direction are connected to the column signal processing circuit 4. The column signal processing circuit 4 performs analog/digital (AD) conversion of a plurality of pixel signals supplied via the plurality of signal lines L1. More specifically, the column signal processing circuit 4 compares pixel signals on the respective signal lines L1 with a reference signal, and generates digital pixel signals on the basis of a time until the signal levels of the pixel signals and the reference signal are matched. The column signal processing circuit 4 sequentially generates digital pixel signals (P-phase signals) of a reset level and digital pixel signals (D-phase signals) of a pixel signal level in a floating diffusion layer inside the pixels and performs CDS (Correlated Double Sampling).

The horizontal driving circuit 5 controls a timing to transfer the output signals of the column signal processing circuit 4 to the output circuit 6.

The control circuit 7 controls the vertical driving circuit 3, the column signal processing circuit 4, and the horizontal driving circuit 5. The control circuit 7 generates a reference signal to be used by the column signal processing circuit 4 to perform AD conversion.

The light detection device 1 of FIG. 1 can be configured by laminating a first substrate in which the pixel array unit 2 and the like are arranged and a second substrate in which the vertical driving circuit 3, the column signal processing circuit 4, the horizontal driving circuit 5, the output circuit 6, the control circuit 7, and the like are arranged through Cu—Cu connection, bumps, vias, or the like.

The photodiodes PD of the respective pixels inside the pixel array unit 2 are arranged in the photoelectric conversion region. Although omitted in FIG. 1, the imaging device according to the present embodiment includes a light control region (also called a light guide region herein) laminated on the photoelectric conversion region. As will be described later, the light control region converts the optical characteristics of incident light using fine structures 15, which may comprise nanostructures having dimensions in nanometers nm. For example, the light control region is capable of to improving quantum efficiency Qe in the photoelectric conversion region with an increase in the light path length of incident light. It should be appreciated that although the description may refer to a particular region as a region that encompasses all pixel units 10, it may also be said that each pixel unit 10 or pixel 10c comprises the particular region. For example, the photoelectric conversion region 11 may be discussed as a region that encompasses all pixel units 10, and it may also be said that each pixel unit 10 comprises one or more photoelectric conversion regions 11 and/or that each pixel 10c comprises a photoelectric conversion region 11.

FIG. 2 is a diagram for describing the principle of fine structures. FIG. 2 shows an example in which an A region and a B region each allowing light to pass therethrough are adjacent to each other. The A region and the B region have a length L in a light propagating direction. The B region has a refractive index of n0. On the other hand, the A region has a refractive index of n0 in a part (L−L1) thereof and a refractive index of n1 in a remaining part (L1) thereof.

A light path length dA of the A region and a light path length dB of the B region of FIG. 2 are expressed by the following formulas (1) and (2), respectively.

$$dA = n 0 \times ( L - L 1 ) + n 1 \times L 1 \qquad ( 1 )$$

$$dB = n 0 \times L \qquad ( 2 )$$

Accordingly, a light path length difference Ad between the A region and the B region is expressed by the following formula (3).

$$Δ d = dB - dA = L 1 ( n 0 - n 1 ) \qquad ( 3 )$$

Further, a phase difference o between the A region and the B region is expressed by the following formula (4).

$$φ = 2 π L 1 ( n 0 - n 1 ) / λ \qquad ( 4 )$$

As shown in formula (4), the light path length of light propagating through the A region and the B region changes according to a refractive index difference between the A region and the B region, and the light causes a difference in its propagating direction according to the refractive index difference. The difference in the propagating direction depends on the wavelength of the light.

As described above, it is possible to change the light path length and the propagating direction of light by making the light incident on the fine structures. Further, it is possible to variously change the light path length and the propagating direction of light by adjusting the width, the shape, the direction, the number, or the like of the fine structures.

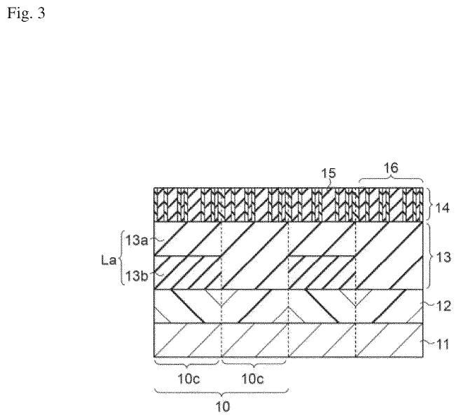

FIG. 3 is a schematic cross-sectional diagram of the light detection device 1 according to the present embodiment. The light detection device 1 of FIG. 3 includes a structure in which a photoelectric conversion region 11, a color filter region 12, a refraction direction adjustment member (also called a refraction structure herein) 13, and a light control region (also called a light guide region herein) 14 are laminated. In FIG. 3, an anti-reflection film and a fixed charge film not shown may be arranged between the photoelectric conversion region 11 and the color filter region 12. The fixed charge film is a film having fixed charges and suppresses the occurrence of a dark current in the interface of a semiconductor substrate.

The photoelectric conversion region 11 has a plurality of pixel units 10 each of which performs photoelectric conversion. A respective pixel units 10 may include one or more color pixels 10c (10r, 10g, and/or 10b). For example, a pixel unit 10 includes one pixel 10c, two pixel 10c, four pixels 10c, or eight pixels 10c. The photoelectric conversion region 11 has a photodiode for each of the color pixels 10c.

The color filter region 12 has color filter parts or color filters 12c (12r, 12g, and 12b) that allow the light of wavelengths corresponding to the respective color pixels 10c to pass therethrough. Since each of the pixel units 10 is constituted by the plurality of color pixels 10c, the color filter region 12 has the plurality of color filter parts 12c for each of the color pixels 10c. The color filter parts 12c allow the light of wavelength bands of corresponding colors to pass therethrough.

The refraction direction adjustment member 13 is arranged between the light control region 14 and the photoelectric conversion region 11 and adjusts the refraction direction of light emitted from the light control region 14. More specifically, the refraction direction adjustment member 13 is arranged between the light control region 14 and the color filter region 12 and adjusts the refraction direction of light emitted from the light control region 14. Stated another way, a refraction structure 13 is arranged between a light guide region 14 and a photoelectric conversion region 11 and causes light exiting the light guide region 14 to refract in a refraction direction. The refraction direction may vary according to a wavelength of light exiting the light guide region 14. The refraction direction adjustment member 13 has, for each of the plurality of pixels 10, a laminated body La that adjusts a refraction direction according to the wavelength of incident light. The refraction direction adjustment member 13 has two or more laminated bodies La that correspond to the light of two or more wavelengths incident on the light control region 14, and the two or more laminated bodies La have refractive indexes different from each other. The color filter part 12c is not included in the refraction direction adjustment member 13.

The light control region 14 is arranged on a light incident direction side with respect to the refraction direction adjustment member 13. The light control region 14 has the fine structures 15 that control the propagating direction of incident light. The fine structures 15 will be described later. In the present specification, the light control region 14 will be called a color splitter 14 depending on the circumstances.

The photoelectric conversion region 11 has the plurality of color pixels 10c for each of the plurality of pixels 10. The color splitter 14 has a pixel control region 16 (also called a pixel light guide region) for each of the plurality of color pixels 10c, and the respective pixel control regions 16 have the fine structures 15. The refraction direction adjustment member 13 adjusts the refraction direction of light emitted from the pixel control region 16 corresponding to at least one color pixel 10c among the plurality of pixel control regions 16 corresponding to the plurality of color pixels 10c.

The refraction direction adjustment member 13 makes the refraction directions of light different from each other, the light being emitted from two or more of the pixel control regions 16 corresponding to two or more of the color pixels 10c of different colors among the plurality of pixel control regions 16 corresponding to the plurality of color pixels 10c. Like this, the refraction direction adjustment member 13 changes a refraction direction for each of the wavelengths of colors. Further, the refraction direction adjustment member 13 may emit light without changing a refraction direction for the wavelength of a certain color.

The refraction direction adjustment member 13 is arranged in a region on which light emitted from two or more of the pixel control regions 16 corresponding to two or more of the color pixels 10c is incident. For example, the refraction direction adjustment member 13 may adjust the refraction directions of the light of wavelengths corresponding to a red pixel 10r and a green pixel 10g, but may not adjust the refraction direction of the light of a wavelength corresponding to a blue pixel 10b.

The refractive indexes of one or more light transmission layers provided in each of the two or more laminated bodies La constituting the refraction direction adjustment member 13 are different from each other. By setting the different refractive indexes in the light transmission layers, it is possible to change a refraction direction for each wavelength of incident light.

Each of the two or more laminated bodies La constituting the refraction direction adjustment member 13 may have a first light transmission layer 13a and a second light transmission layer 13b laminated with each other. Further, the first light transmission layers 13a of the two or more laminated bodies La may have the same refractive index, and the second light transmission layers 13b thereof may have refractive indexes different from each other.

The refraction direction adjustment member 13 may emit light without changing the refraction direction of the light emitted from the pixel control regions 16 corresponding to the color pixels 10c of a specific color (for example, green) among the plurality of color pixels 10c, and may separately adjust the refraction directions of light emitted from the pixel control regions 16 corresponding to the color pixels 10c of colors (for example, red and blue) other than the specific color.

The refraction direction adjustment member 13 may adjust the refraction direction of light emitted from at least a part of the pixel control regions 16 so that the focal distances of the light emitted from the plurality of pixel control regions 16 corresponding to the plurality of color pixels 10c become uniform.

The refraction direction adjustment member 13 may contain a material having a refractive index n adjusted so that a focal position f expressed by f=φ×D×n/(c×λ) becomes uniform at all wavelengths λ when the wavelength of light emitted from the color splitter 14 is represented by λ, the refractive index of the refraction direction adjustment member 13 is represented by n, a beam diameter on the light incident surface of the color splitter 14 is represented by D, a beam diameter on the light receiving surface of the photoelectric conversion region 11 is represented by φ, the focal position of light emitted from the refraction direction adjustment member is represented by f, and a coefficient composed of a prescribed real number is represented by c.

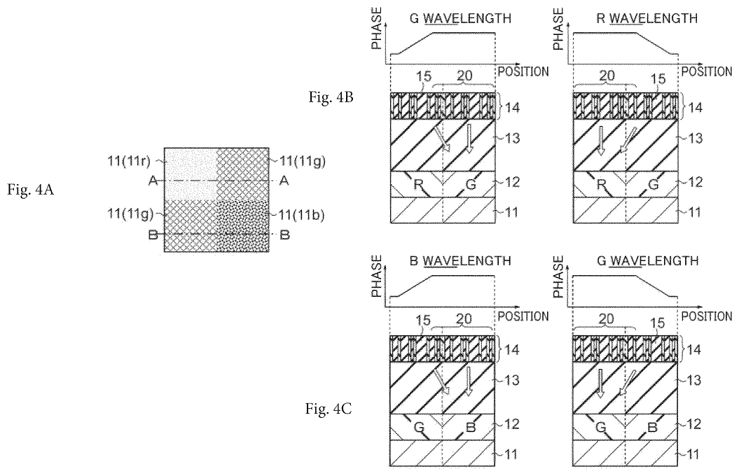

FIG. 4 is a diagram for describing the above color splitter 14. More specifically, FIG. 4 is a diagram for describing the function of the color splitter 14 in a case in which the color pixels 10c are arranged in the photoelectric conversion region 11 in Bayer arrangement. In the Bayer arrangement, one pixel unit 10 is constituted by four color pixels 10c. The four color pixels 10c include one red pixel 10r, two green pixels 10g, and one blue pixel 10b.

FIG. 4A is a plane diagram of four color pixels 10c constituting the Bayer arrangement. FIGS. 4B and 4C are cross-sectional diagrams taken along the line A-A in FIG. 4A, and FIGS. 4D and 4E are cross-sectional diagrams taken along the line B-B in FIG. 4A. FIGS. 4B and 4E show the phase distribution and the propagating direction of the light of the wavelength of green, FIG. 4C shows the phase distribution and the propagating direction of the light of the wavelength of red, and FIG. 4D shows the phase distribution and the propagating direction of the light of the wavelength of blue.

As shown in FIGS. 4A to 4E, the color splitter 14 is able to refract the light of the respective colors (wavelengths) in refraction directions corresponding to the respective colors. Accordingly, the respective color pixels are also able to make light having been incident on peripheral color pixel regions incident on the respective color pixels.

The color splitter 14 is provided with the plurality of column-shaped fine structures 15 and has different opening ranges 20 to take in light for each wavelength of light. In the A-A line direction of FIG. 4A, the light of the wavelength of green is taken in from an opening range 20 at the origin of an arrow shown in the figure and received by a green pixel 10g, and the light of the wavelength of red is taken in from an opening range 20 at the origin of an arrow shown in the figure and received by a red pixel 10r as shown in FIGS. 4B an 4C. Similarly, in the B-B line direction of FIG. 4A, the light of the wavelength of green is taken in from an opening range 20 at the origin of an arrow shown in the figure and received by a green pixel 10g, and the light of the wavelength of blue is taken in from an opening range 20 at the origin of an arrow shown in the figure and received by a blue pixel 10b as shown in FIGS. 4D an 4E.

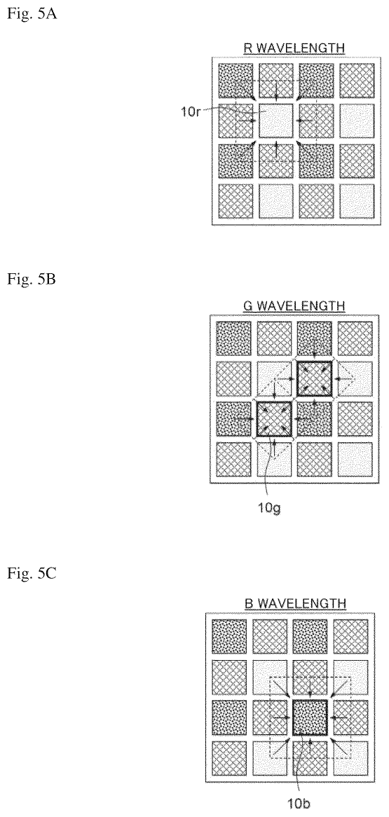

FIGS. 5A, 5B, and 5C are plane diagrams schematically showing directions in which respective color pixels 10c take in light from peripheries. As shown in FIG. 5A, a red pixel 10r takes in light within an opening range 20 over eight peripheral color pixels 10c. Two green pixels 10g exist in one pixel 10, and the respective green pixels 10g take in light within an opening range 20 over four peripheral color pixels 10c as shown in FIG. 5B. As shown in FIG. 5C, a blue pixel 10b takes in light within an opening range 20 over eight peripheral color pixels 10c.

FIG. 6 is a diagram for describing the focal distance of light having passed through the color splitter 14. Light having been incident on the pixel control regions 16 corresponding to the respective color pixels 10c inside the color splitter 14 is incident on the regions of the color pixels 10c on the light receiving surface of the photoelectric conversion region 11. The following formula (1) is established when the diameter of the light incident ranges (also called the opening ranges 20) of the pixel control regions 16 is represented by D, a focal distance is represented by f, a beam diameter at a focal position is represented by φ, the wavelength of light is λ, and a coefficient corresponding to a beam shape is represented by c.

$$φ = c \times λ f / D \qquad ( 1 )$$

The focal distance f is expressed by the following formula (2) when the formula (1) is transformed.

$$f = φ \times D \times n / ( c \times λ ) \qquad ( 2 )$$

Most desirably, the focal distance f is uniform on the light receiving surface of the photoelectric conversion region 11. However, since the wavelength λ is different for each color as shown in formula (2), the focal distance f is different for each color. Therefore, the beam diameter on the light receiving surface of the photoelectric conversion region 11 does not become the same for each color.

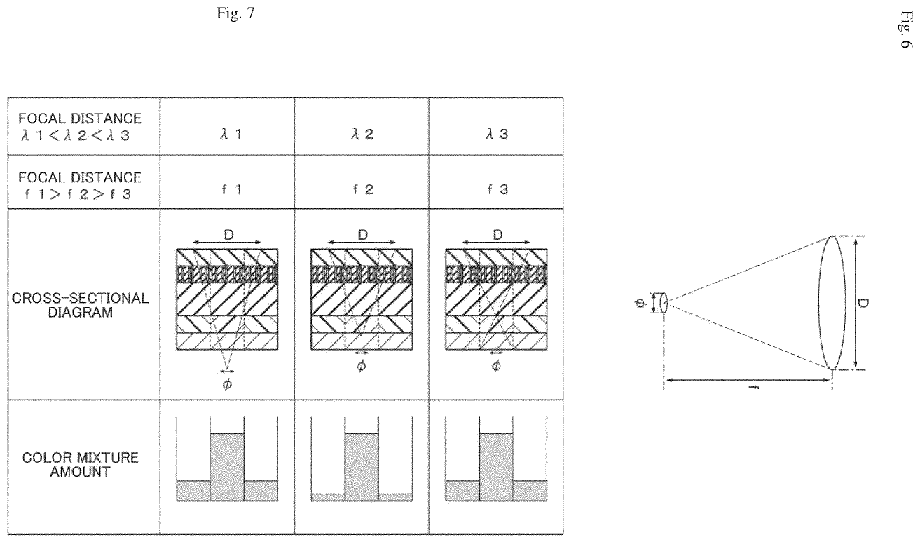

FIG. 7 is a diagram showing focal distances f1, f2, and f3, light propagating directions, and color mixture amounts with respect to, for example, three wavelengths λ1, λ2, and λ3 corresponding to the three colors of red, green, and blue. The relationship between the focal distances is expressed as f1>f2 >f3 when the relationship between the wavelengths is assumed as λ1<λ2<λ3. FIG. 7 shows an example in which an image is formed on the light receiving surface of the photoelectric conversion region 11 by the light of the intermediate wavelength λ2. In the case of FIG. 7, the shortest wavelength λ1 causes rear focus, and the longest wavelength λ3 causes front focus. In both cases of the rear focus and the front focus, a beam diameter on the light receiving surface of the photoelectric conversion region 11 becomes large. Therefore, color mixture is likely to occur.

As described above, the focal distances become different depending on the wavelengths when the plurality of pixel control regions 16 inside the color splitter 14 on which the light of different wavelengths is incident have the same fine structures 15. Therefore, beam diameters become different on the light receiving surface of the photoelectric conversion region 11, and color mixture is likely to occur.

FIG. 8 is a diagram for describing the optical function of the refraction direction adjustment member 13 according to the present embodiment. The refraction direction adjustment member 13 has, for each of the pixel control regions 16 corresponding to at least a part of the color pixels 10c, the laminated body La in which the plurality of light transmission layers are laminated. FIG. 8 shows an example in which the refraction direction adjustment member 13 has the laminated bodies La in which the first light transmission layer 13a and the second light transmission layer 13b are laminated.

For example, for respective red pixels 10r and blue pixels 10b, refractive indexes n2 of the second light transmission layers 13b are set to be different from each other, while refractive indexes n1 of the first light transmission layers 13a are set to be the same. As an example, the refractive indexes n2 of the second light transmission layers 13b of the refraction direction adjustment member 13 corresponding to red pixels 10r and the refractive indexes n2 of the second light transmission layers 13b of the refraction direction adjustment member 13 corresponding to a blue pixel 10b are set to be different from each other. On the other hand, the refractive indexes n1 of the first light transmission layers 13a are set to be the same for all the color pixels 10c. For green pixels 10g, the refraction direction adjustment member 13 has a single light transmission layer. Note that the refraction direction adjustment member 13 may also have the laminated structure, in which the first light transmission layer 13a and the second light transmission layer 13b are laminated, for the green pixels 10g.

FIG. 8A is a diagram assuming a case that light is incident from the direction of the normal to the light incident surface of the color splitter 14. As shown in FIG. 8A, the laminated bodies La having a multi-layer structure are arranged in regions on which the light of a specific color (wavelength) is incident in the refraction direction adjustment member 13. The laminated bodies La include a structure in which a plurality of light reflection layers having refractive indexes n1 and n2 different from each other are laminated.

In the example of FIG. 8A, the laminated bodies La are arranged in a region on which the light of red is incident and a region on which the light of blue is incident in the refraction direction adjustment member 13. On the other hand, a region on which the light of green is incident in the refraction direction adjustment member 13 may have a single-layer structure or may include a laminated body in which a plurality of light transmission layers having the same refractive index are laminated.

As described above, the refractive indexes of one or more layers in the laminated bodies La are set to be different from each other for each of the wavelengths of colors, whereby it is possible to change the refraction direction of light incident on the refraction direction adjustment member 13 for each of the wavelengths and make focal distances f uniform even if the wavelengths of the colors are different.

FIG. 8B is a diagram assuming a case that light is incident from a direction inclined with respect to the direction of the normal to the light incident surface of the color splitter 14. In this case, light having passed through the color splitter 14 and the refraction direction adjustment member 13 may not be incident on an intended light receiving position on the photoelectric conversion region 11, and pupil correction is required. Therefore, FIG. 8B shows an example in which the relative positional relationship between the refraction direction adjustment member 13 and the photoelectric conversion region 11 is shifted along the light incident surface to perform the pupil correction.

In the examples of FIGS. 8A and 8B, an image of the light of the wavelengths of all the colors is formed on the light receiving surface of the photoelectric conversion region 11 at substantially the same beam diameter by the refraction direction adjustment member 13. Thus, it is possible to suppress color mixture.

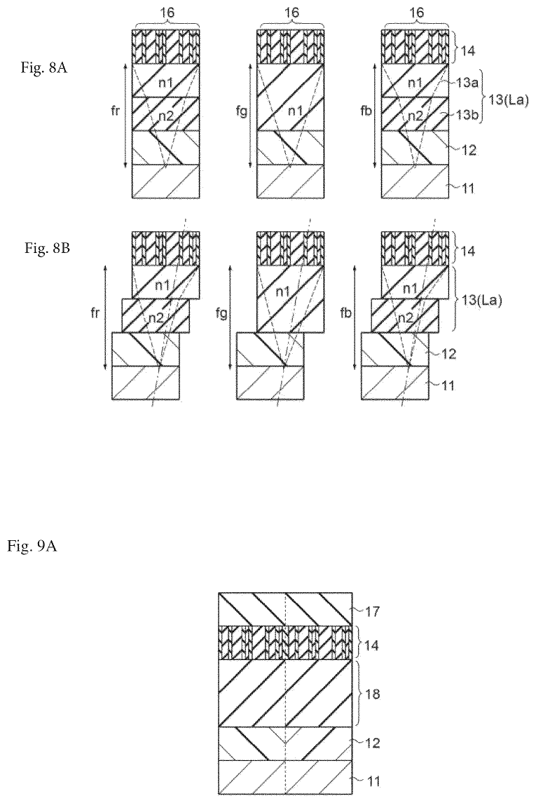

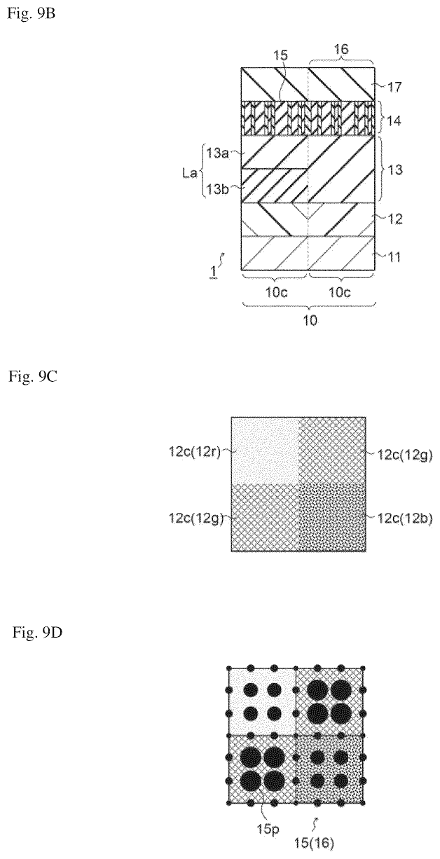

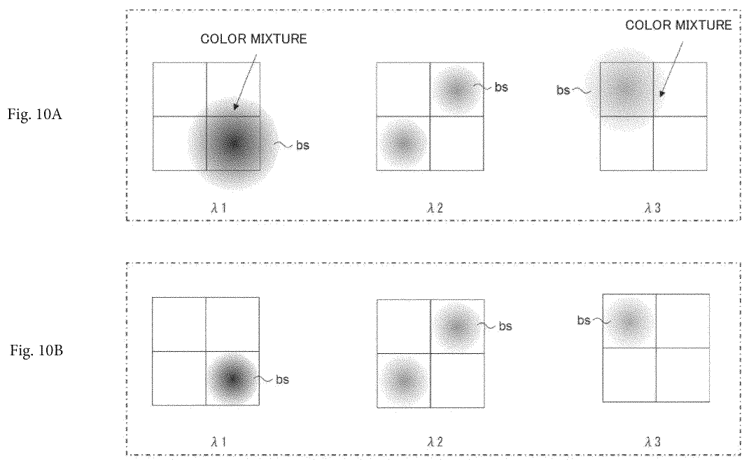

FIG. 9A is a cross-sectional diagram of a light detection device 100 in which an insulating layer 18 is provided instead of the refraction direction adjustment member 13, and FIG. 9B is a cross-sectional diagram of the light detection device 1 in which the refraction direction adjustment member 13 is provided. In FIGS. 9A and 9B, an antireflection layer 17 is arranged on the upper surface of the light control region 14. FIG. 9C is a plane diagram of the color filter region 12 of FIGS. 9A and 9B, and FIG. 9D is a plane diagram of the light control region 14 of FIGS. 9A and 9B. As is clear from FIGS. 9C and 9D, the light detection device 100 of FIG. 9A and the light detection device 1 of FIG. 9B have the color filter region 12 of the same structure and the light control region 14 of the same structure.

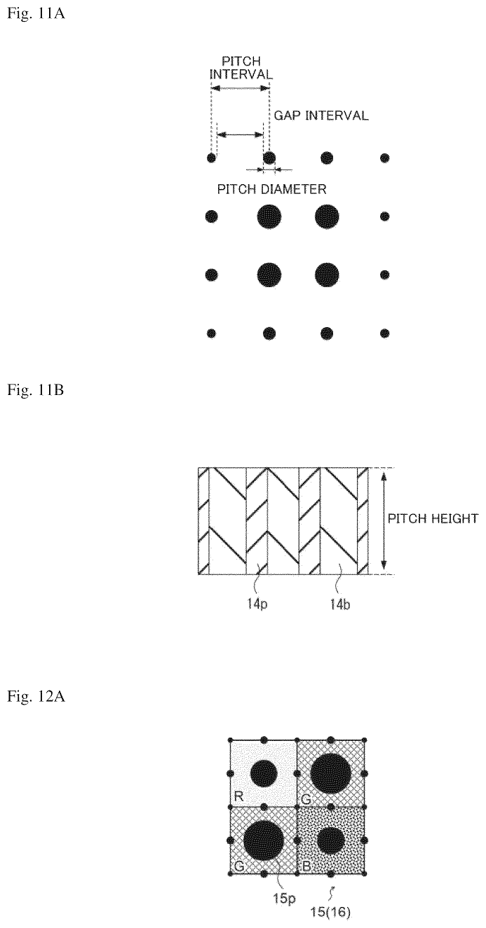

FIG. 10 is a diagram showing beam diameters on the light receiving surface of the photoelectric conversion region 11 in the light detection devices 1 and 100. FIG. 10A is a diagram showing beam diameters bs on the light receiving surface of the photoelectric conversion region 11 in the light detection device 100 of FIG. 9A, and FIG. 10B is a diagram showing beam diameters bs on the light receiving surface of the photoelectric conversion region 11 in the light detection device 1 of FIG. 9B. FIGS. 10A and 10B show the beam diameters bs on the light receiving surface of the photoelectric conversion region 11 that receives the light of three wavelengths 21, 22, and 23 (λ1<λ2<λ3). The lattice-shaped lines of FIGS. 10A and 10B are the boundary regions of the color pixels 10c on the light receiving surface of the photoelectric conversion region 11.

In the case of FIG. 10A, the beam diameters bs of the light of the wavelengths of blue and red enter the adjacent pixel units 10 over the boundaries of the color pixels 10c and cause color mixture. On the other hand, in the case of FIG. 10B, the beam diameters bs remain inside the boundary regions of the color pixels 10c for all the colors and are able to suppress color mixture.

As described above, the color splitter 14 (the light control region 14) is partitioned into the pixel control regions 16 for the respective color pixels 10c. The respective pixel control regions 16 are provided with the fine structures 15.

The fine structures 15 have a plurality of pillar parts 15p each extending in a laminating direction. The plurality of pillar parts 15p are surrounded by a base member 15b. The refractive index of the pillar parts 15p is larger than that of the base member 15b. The material of the pillar parts 15p is an insulating material such as TiO₂. More specifically, the pillar parts 15p are made of a silicon compound such as silicon nitride and silicon carbide, a metal oxide such as titanium oxide, tantalum oxide, niobium oxide, hafnium oxide, indium oxide, and tin oxide, or a complex oxide thereof. Besides, the pillar parts 15p may be made of organic matter such as siloxane. The material of the base member 15b is, for example, an insulating material such as SiO₂.

It is possible to variously control the optical characteristics of the color splitter 14 by changing the configuration of the fine structures 15 of the respective pixel control regions 16 inside the color splitter 14. More specifically, it is possible to arbitrarily control the optical characteristics of the color splitter 14 by controlling at least one of the material (optical constant) of the pillar parts 15p, the material (optical constant) of the base member 15b, the shape of the pillar parts 15p, the height of the pillar parts 15p, the pitch interval (or interval) of the pillar parts 15p, and the gap interval of the pillar parts 15p (or gap between pillar parts 15p) for each of the pixel control regions 16.

FIG. 11A is a plane diagram for describing the pitch diameter (or diameter), the pitch interval, and the gap interval of the pillar parts 15p, and FIG. 11B is a cross-sectional diagram for describing the height of the pillar parts 15p. When the pillar parts 15p have a columnar shape, the pitch diameter represents the diameter of columns. The pitch interval represents the shortest distance between the central positions of two adjacent pillar parts 15p. The gap interval represents the shortest distance between the outer peripheral surfaces of two adjacent pillar parts 15p. The height of the pillar parts 15p represents the length in the laminating direction of the pillar parts 15p.

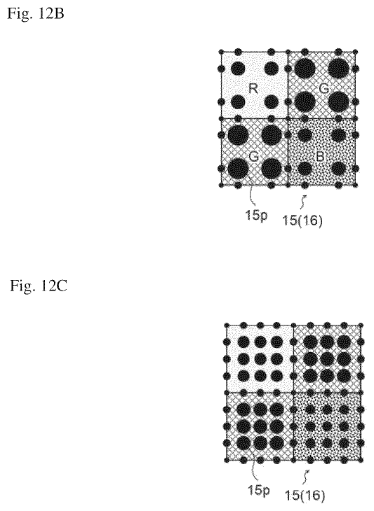

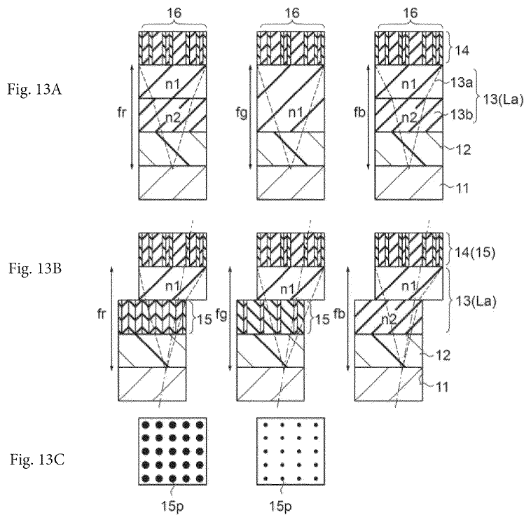

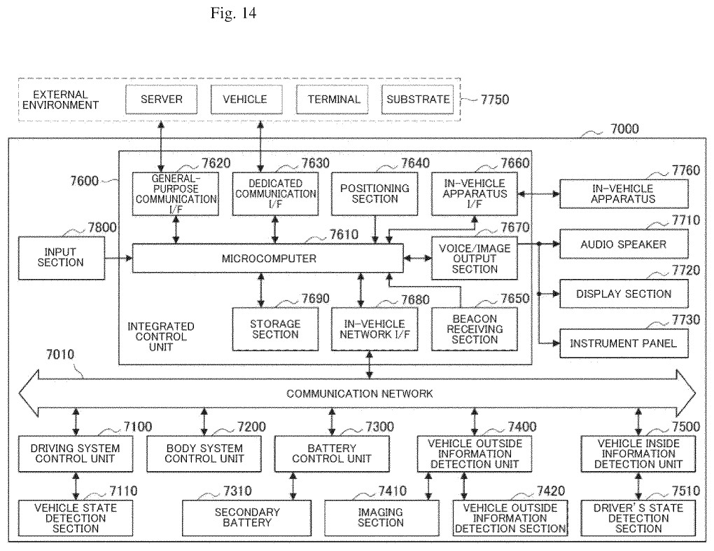

FIGS. 12A, 12B, and 12C each shows an example of the fine structures 15, and various modified examples of the arrangement of the pillar parts 15p are assumed. FIG. 12A is a plane diagram showing a first example of the fine structures 15 inside the color splitter 14. FIG. 12B is a plane diagram showing a second example of the fine structures 15 inside the color splitter 14. FIG. 12C is a plane diagram showing a third example of the fine structures 15 inside the color splitter 14.

In each of FIGS. 12A, 12B, and 12C, the fine structures 15 inside the pixel control regions 16 corresponding to red pixels 10r and green pixels 10g have the same configuration. Further, the fine structures 15 inside the pixel control regions 16 corresponding to two green pixels 10g in the Bayer arrangement have the same configuration. FIGS. 12A, 12B, and 12C each show an example of the fine structures 15, and various modified examples of the fine structures 15 are assumed.

FIG. 8 shows an example in which the refraction direction adjustment member 13 has the two-layer structure of the first light transmission layer 13a and the second light transmission layer 13b. However, it is also possible to form a refraction direction adjustment member by the fine structures 15. FIG. 13 is a cross-sectional diagram showing a modified example of the refraction direction adjustment member 13 shown in FIG. 8. The refraction direction adjustment member 13 of FIG. 13 includes the fine structures 15. More specifically, at least a part of the refraction direction adjustment member 13 has the plurality of fine structures 15 partitioned in units of the color pixels 10c. Further, a part of the refraction direction adjustment member 13 may have a multi-layer structure having refractive indexes different from each other like FIG. 8. That is, the refraction direction adjustment member 13 may include the regions of the multi-layer structure and the regions of the fine structures 15.

FIG. 13A is a diagram assuming a case that light is incident from the direction of the normal to the light incident surface of the color splitter 14. The refraction direction adjustment member 13 of FIG. 13A has a two-layer structure having refractive indexes different from each other like FIG. 8A. In FIG. 13A, the refraction direction adjustment member 13 has the laminated bodies La of the two-layer structure, and the refractive indexes of one or more layers of the laminated bodies La are different from each other for each of the wavelengths of colors. Thus, it is possible to change the refraction direction of light incident on the refraction direction adjustment member 13 for each of the wavelengths and make focal distances f uniform even if the wavelengths of the colors are different.

FIG. 13B is a diagram assuming a case that light is incident from a direction inclined with respect to the direction of the normal to the light incident surface of the color splitter 14. The refraction direction adjustment member 13 of FIG. 13B has the fine structures 15 partitioned in units of the color pixels 10c. As shown in a plane diagram of FIG. 13C, the fine structures 15 have the plurality of pillar parts 15p. It is possible to perform the adjustment of focal distances and pupil correction by controlling at least one of the material (optical constant) of the pillar parts 15p, the material (optical constant) of the base member, the shape of the pillar parts 15p, the height of the pillar parts 15p, the pitch interval of the pillar parts 15p, and the gap interval of the pillar parts 15p.

As described above, the refraction direction adjustment member 13 is provided between the color splitter 14 and the photoelectric conversion region 11 or between the color splitter 14 and the color filter region 12 in the light detection device 1 according to the present embodiment. Therefore, it is possible to adjust the refraction direction of light emitted from the color splitter 14. Accordingly, it is possible to form an image of the light of a plurality of wavelengths corresponding to a plurality of colors on the light receiving surface of the photoelectric conversion region 11 at the beam diameter of the same size. Thus, it is possible to suppress color mixture.

The refraction direction adjustment member 13 may be constituted by, for example, the laminated bodies La including at least two light transmission layers having refractive indexes different from each other. It is possible to make the focal distances of the light of all the wavelengths uniform by setting different refractive indexes in some of the light transmission layers of the laminated bodies La for each wavelength of incident light.

### Applied Examples

The technology according to the present disclosure is applicable to various products. For example, the technology according to the present disclosure may be realized as devices mounted on any type of mobile bodies such as automobiles, electric automobiles, hybrid electric automobiles, automatic two-wheeled vehicles, bikes, personal mobilities, airplanes, drones, ships, robots, construction machines, and agricultural machines (tractors).

FIG. 14 is a block diagram showing a schematic configuration example of a vehicle control system 7000 that is an example of a mobile body control system to which the technology according to the present disclosure can be applied. The vehicle control system 7000 includes a plurality of electronic control units connected to each other via a communication network 7010. In the example shown in FIG. 14, the vehicle control system 7000 includes a driving system control unit 7100, a body system control unit 7200, a battery control unit 7300, a vehicle outside information detection unit 7400, a vehicle inside information detection unit 7500, and an integrated control unit 7600. The communication network 7010 that connects the plurality of control units to each other may be an in-vehicle communication network complying with arbitrary standards such as CAN (Controller Area Network), LIN (Local Interconnect Network), LAN (Local Area Network), and FlexRay™.

The respective control units include a microcomputer that performs computation processing according to various programs, a storage unit that stores a program run by the microcomputer, parameters used for various computation, or the like, and a driving circuit that drives various devices to be controlled. The respective control units include a network I/F used to perform communication with other control units via the communication network 7010, and include a communication I/F used to perform wired or wireless communication with devices, sensors, or the like inside and outside a vehicle. FIG. 14 shows, as the functional configurations of the integrated control unit 7600, a microcomputer 7610, a general-purpose communication I/F 7620, a dedicated communication I/F 7630, a positioning section 7640, a beacon receiving section 7650, an in-vehicle apparatus I/F 7660, a voice/image output section 7670, an in-vehicle network I/F 7680, and a storage section 7690. Other control units also similarly include a microcomputer, a communication I/F, a storage unit, or the like.

The driving system control unit 7100 controls the movement of a device relating to the driving system of the vehicle according to various programs. For example, the driving system control unit 7100 functions as a driving force generation device such as an internal combustion engine and a driving motor used to generate the driving force of the vehicle, a driving force transmission mechanism used to transmit a driving force to wheels, a steering mechanism that adjusts the steering of the vehicle, and a control device such as a braking control device that generates the braking force of the vehicle. The driving system control unit 7100 may also have a function such as an ABS (Antilock Brake System) and an ESC (Electronic Stability Control) as a control device.

A vehicle state detection section 7110 is connected to the driving system control unit 7100. The vehicle state detection section 7110 includes, for example, at least one of a gyro sensor that detects the angular speed of the shaft rotational movement of a vehicle body, an acceleration sensor that detects the acceleration of the vehicle, and a sensor used to detect the operation amount of an accelerator pedal, the operation amount of a brake pedal, the steering angle of a steering wheel, the rotation number of an engine, the rotational speed of wheels, or the like. The driving system control unit 7100 performs computation processing using a signal input from the vehicle state detection section 7110 and controls an internal combustion engine, a driving motor, an electric power steering device, a braking device, or the like.

The body system control unit 7200 controls the movement of various devices installed in the vehicle body according to various programs. For example, the body system control unit 7200 functions as the control device of a keyless entry system, a smart key system, a power window device, and various lamps such as a head lamp, a back lamp, a brake lamp, a blinker, and a fog lamp. In this case, electric waves or the signals of various switches emitted from a mobile machine substituting for a key can be input to the body system control unit 7200. With the input of these electric waves or signals, the body system control unit 7200 controls the door lock device, the power window device, the lamps, or the like of the vehicle.

The battery control unit 7300 controls a secondary battery 7310 that is the power supply source of a driving motor according to various programs. For example, information such as a battery temperature, a battery output voltage, a remaining battery capacity is input to the battery control unit 7300 from a battery device including the secondary battery 7310. The battery control unit 7300 performs computation processing using the signals of these information items to perform the temperature regulation control of the secondary battery 7310, the control of a cooling device or the like provided in the battery device.

The vehicle outside information detection unit 7400 detects the vehicle outside information of the vehicle on which the vehicle control system 7000 is mounted. For example, at least one of an imaging section 7410 and a vehicle outside information detection section 7420 is connected to the vehicle outside information detection unit 7400. The imaging section 7410 includes at least one of a ToF (Time of Flight) camera, a stereo camera, a monocular camera, an infrared camera, and any other camera. The vehicle outside information detection section 7420 includes, for example, at least one of an environment sensor used to detect current weather or atmospheric conditions and a surrounding information detection sensor used to detect other vehicles, obstacles, pedestrians, or the like around the vehicle on which the vehicle control system 7000 is mounted.

The environment sensor may be, for example, at least one of a raindrop sensor that detects a rainy weather, a fog sensor that detects a fog, a sunshine sensor that detects a sunshine degree, and a snow sensor that detects snowfall. The surrounding information detection sensor may be at least one of an ultrasonic wave sensor, a radar device, and a LIDAR (Light Detection and Ranging, Laser Imaging Detection and Ranging) device. The imaging section 7410 and the vehicle outside information detection section 7420 may be provided as independent sensors or devices, or may be provided as a device in which a plurality of sensors or devices are integrated with each other.

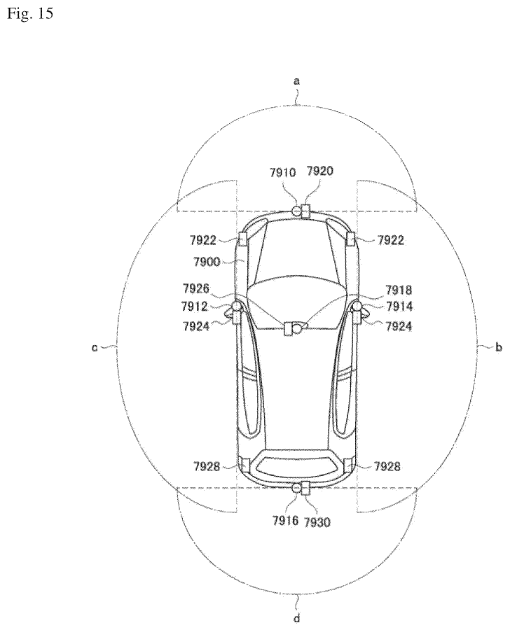

Here, FIG. 15 shows an example of the installation positions of the imaging section 7410 and the vehicle outside information detection section 7420. Imaging sections 7910, 7912, 7914 7916, and 7918 are installed at, for example, at least one of the front nose, the side mirrors, the rear bumper, the back door, and the upper part of a windshield inside the vehicle of a vehicle 7900. The imaging section 7910 provided at the front nose and the imaging section 7918 provided at the upper part of the windshield inside the vehicle mainly capture an image on the front side of the vehicle 7900. The imaging sections 7912 and 7914 provided at the side mirrors mainly capture images on the lateral sides of the vehicle 7900. The imaging section 7916 provided at the rear bumper or the back door mainly captures an image on the rear side of the vehicle 7900. The imaging section 7918 provided at the upper part of the windshield inside the vehicle is mainly used to detect preceding vehicles, pedestrians, obstacles, traffic signals, traffic signs, lanes, or the like.

Note that FIG. 15 shows an example of the imaging range of each of the imaging sections 7910, 7912, 7914, and 7916. An imaging range a shows the imaging range of the imaging section 7910 provided at the front nose, imaging ranges b and c show the imaging ranges of the imaging sections 7912 and 7914 provided at the respective side mirrors, and an imaging range d shows the imaging range of the imaging section 7916 provided at the rear bumper or the back door. For example, a bird's-eye view of the vehicle 7900 seen from above is obtained by superimposing image data captured by the imaging sections 7910, 7912, 7914, and 7916 one upon another.

Vehicle outside information detection sections 7920, 7922, 7924, 7926, 7928, and 7930 provided at the front, the rear, the sides, the corners, and the upper part of the windshield inside the vehicle of the vehicle 7900 may be, for example, ultrasonic sensors or radar devices. The vehicle outside information detection sections 7920, 7926, and 7930 provided at the front nose, the rear bumper, the back door, and the upper part of the windshield inside the vehicle of the vehicle 7900 may be, for example, LIDAR devices. The vehicle outside information detection sections 7920 to 7930 are mainly used to detect preceding vehicles, pedestrians, obstacles, or the like.

Referring back to FIG. 14, the description will be continued. The vehicle outside information detection unit 7400 causes the imaging section 7410 to capture an image outside the vehicle and receives the data of the captured image. Further, the vehicle outside information detection unit 7400 receives detected information from the connected vehicle outside information detection section 7420. When the vehicle outside information detection section 7420 is an ultrasonic sensor, a radar device, or a LIDAR device, the vehicle outside information detection unit 7400 causes the vehicle outside information detection section 7420 to emit ultrasonic waves, electromagnetic waves, or the like and receives the information of received reflected waves. The vehicle outside information detection unit 7400 may perform the object detection processing or distance detection processing of persons, vehicles, obstacles, signs, characters on road surfaces, or the like on the basis of the received information. The vehicle outside information detection unit 7400 may perform environment recognition processing to recognize rainfall, fog, road surface conditions, or the like on the basis of the received information. The vehicle outside information detection unit 7400 may calculate distances to objects outside the vehicle on the basis of the received information.

Further, the vehicle outside information detection unit 7400 may perform image recognition processing or distance detection processing to recognize persons, vehicles, obstacles, signs, characters on road surfaces, or the like on the basis of the received image data. The vehicle outside information detection unit 7400 may perform processing such as distortion correction and alignment on the received image data and combine image data captured by different imaging sections 7410 with each other to generate a bird's-eye view or a panorama image. The vehicle outside information detection unit 7400 may perform viewpoint conversion processing using image data captured by different imaging sections 7410.

The vehicle inside information detection unit 7500 detects information inside the vehicle. A driver's state detection section 7510 that detects a driver's state is, for example, connected to the vehicle inside information detection unit 7500. The driver's state detection section 7510 may include a camera that captures an image of a driver, a biosensor that detects driver's biological information, a microphone that collects voice inside the vehicle, or the like. The biosensor is provided at, for example, a seat surface, a steering wheel, or the like and detects the biological information of an occupant sitting on a seat or a driver gripping the steering wheel. On the basis of detected information input from the driver's state detection section 7510, the vehicle inside information detection unit 7500 may calculate a driver's fatigue degree or a concentration degree or determine whether a driver is dozing at the wheel. The vehicle inside information detection unit 7500 may perform processing such as noise cancelling processing on a collected voice signal.

The integrated control unit 7600 controls general movement inside the vehicle control system 7000 according to various programs. An input section 7800 is connected to the integrated control unit 7600. The input section 7800 is realized by, for example, a device such as a touch panel, a button, a microphone, a switch, and a lever through which an occupant can perform input operation. Data obtained by performing the voice recognition of voice input through a microphone may be input to the integrated control unit 7600. The input section 7800 may be, for example, a remote control device that uses infrared rays or other electric waves or may be an external connection apparatus such as a mobile phone and a PDA (Personal Digital Assistant) that corresponds to the operation of the vehicle control system 7000. The input section 7800 may be a camera. In this case, an occupant is allowed to input information by gesture. Alternatively, data obtained by detecting the movement of a wearable device attached to an occupant may be input. In addition, the input section 7800 may include an input control circuit that generates an input signal on the basis of information input by an occupant or the like through the input section 7800 and outputs the generated input signal to the integrated control unit 7600, or the like. Through the operation of the input section 7800, the occupant inputs various data or provide instructions to perform a processing operation with respect to the vehicle control system 7000.

The storage section 7690 may include a ROM (Read Only Memory) that stores various programs run by a microcomputer and a RAM (Random Access Memory) that stores various parameters, computation results, sensor values, or the like. Further, the storage section 7690 may be realized by a magnetic storage device such as an HDD (Hard Disc Drive), a semiconductor storage device, an optical storage device, a magneto-optical storage device, or the like.

The general-purpose communication I/F 7620 is a general-purpose communication I/F that mediates communication with various apparatuses existing in an external environment 7750. The general-purpose communication I/F 7620 may implement a cellular communication protocol such as GSM™ (Global System of Mobile communications), WiMAX™, LTE™ (Long Term Evolution), and LTE-A (LTE-Advanced) or other wireless communication protocols such as wireless LAN (also called Wi-Fi™) and Bluetooth™. The general-purpose communication I/F 7620 may be connected to, for example, an apparatus (for example, an application server or a control server) existing on an external network (for example, the Internet, a cloud network, or a network unique to a business operator) via, for example, a base station or an access point. Further, the general-purpose communication I/F 7620 may be connected to a terminal (for example, a driver, a pedestrian, a shop terminal, or an MTC (Machine Type Communication) terminal) existing near the vehicle using, for example, a P2P (Peer To Peer) technology.

The dedicated communication I/F 7630 is a communication I/F that supports a communication protocol designed to be used in the vehicle. The dedicated communication I/F 7630 may implement, for example, a standard protocol such as WAVE (Wireless Access in Vehicle Environment) that is a combination of IEEE802.11p of a lower layer and IEEE1609 of an upper layer, DSRC (Dedicated Short Range Communications), and a cellular communication protocol. The dedicated communication I/F 7630 typically performs V2X communication that is a concept including one or more of vehicle to vehicle communication, vehicle to infrastructure communication, vehicle to home communication, and vehicle to pedestrian communication.

The positioning section 7640 receives, for example, a GNSS signal from a GNSS (Global Navigation Satellite System) (for example, a GPS signal from a GPS (Global Positioning System) satellite) to perform positioning and generates positional information including the latitude, the longitude, and the altitude of the vehicle. Note that the positioning section 7640 may specify a current position through the exchange of a signal with a wireless access point, or may acquire positional information from a terminal such as a mobile telephone, a PHS, and a smart phone having a positioning function.

The beacon receiving section 7650 receives, for example, electric waves or electromagnetic waves emitted from a wireless station or the like provided on a road and acquires information such as a current position, a traffic jam, suspension of traffic, and a required time. Note that the function of the beacon receiving section 7650 may be included in the above dedicated communication I/F 7630.

The in-vehicle apparatus I/F 7660 is a communication interface that mediates the connection between the microcomputer 7610 and various in-vehicle apparatuses 7760 existing inside the vehicle. The in-vehicle apparatus I/F 7660 may establish wireless connection using a wireless communication protocol such as a wireless LAN, Bluetooth™, NFC (Near Field Communication), and WUSB (Wireless USB). Further, the in-vehicle apparatus I/F 7660 may establish wired connection of USB (Universal Serial Bus), HDMI™ (High-Definition Multimedia Interface), MHL (Mobile High-definition Link), or the like via a connection terminal (and a cable where necessary) not shown. The in-vehicle apparatuses 7760 may include, for example, at least one of a mobile apparatus or a wearable apparatus possessed by an occupant and an information device transported or attached to the vehicle. Further, the in-vehicle apparatuses 7760 may include a navigation apparatus that searches for a path to an arbitrary goal. The in-vehicle apparatus I/F 7660 exchanges a control signal or a data signal with the in-vehicle apparatuses 7760.

The in-vehicle network I/F 7680 is an interface that mediates the communication between the microcomputer 7610 and the communication network 7010. The in-vehicle network I/F 7680 transmits/receives a signal or the like in accordance with a prescribed protocol supported by the communication network 7010.

The microcomputer 7610 of the integrated control unit 7600 controls the vehicle control system 7000 according to various programs on the basis information acquired via at least one of the general-purpose communication I/F 7620, the dedicated communication I/F 7630, the positioning section 7640, the beacon receiving section 7650, the in-vehicle apparatus I/F 7660, and the in-vehicle network I/F 7680. For example, the microcomputer 7610 may compute the control target value of a driving force generation device, a steering mechanism, or a braking device on the basis of acquired information inside and outside the vehicle and output control instructions to the driving system control unit 7100. For example, the microcomputer 7610 may perform cooperative control for the purpose of realizing the function of an ADAS (Advanced Driver Assistance System) including the collision avoidance or impact alleviation of the vehicle, following travel based on a following distance, vehicle speed keep travel, the collision warning of the vehicle, the lane deviation warning of the vehicle, or the like. Further, the microcomputer 7610 may perform cooperative control for the purpose of performing automated driving to autonomously travel without the operation of a driver or the like by controlling a driving force generation device, a steering mechanism, a braking device, or the like on the basis of acquired information around the vehicle.

The microcomputer 7610 may generate three-dimensional distance information between the vehicle and objects such as surrounding structures and persons on the basis of information acquired via at least one of the general-purpose communication I/F 7620, the dedicated communication I/F 7630, the positioning section 7640, the beacon receiving section 7650, the in-vehicle apparatus I/F 7660, and the in-vehicle network I/F 7680, and generate local map information including the surrounding information of the current position of the vehicle. Further, the microcomputer 7610 may predict a danger such as the collision of the vehicle, the proximity of pedestrians or the like, and approach to closed roads on the basis of acquired information and generate a warning signal. The warning signal may be a signal used to produce a warning sound or light up a warning lamp.

The voice/image output section 7670 transmits the output signal of at least one of voice and an image to an output device able to visually or audibly notify an occupant of the vehicle or the outside of the vehicle of information. In the example of FIG. 14, an audio speaker 7710, a display section 7720, and an instrument panel 7730 are illustrated as output devices. The display section 7720 may include, for example, at least one of an onboard display and a head-up display. The display section 7720 may have an AR (Augmented Reality) display function. The output device may also be any other device such as a wearable device such as a glass type display attached to an occupant, a projector, and a lamp other than these devices. When the output device is a display device, the display device visually displays the results of various processing performed by the microcomputer 7610 or information received from other control units in various forms such as text, an image, a table, and a graph. Further, when the output device is a voice output device, the voice output device converts an audio signal composed of reproduced voice data, acoustic data, or the like into an analog signal and audibly outputs the converted analog signal.

Note that in the example shown in FIG. 14, at least two control units connected to each other via the communication network 7010 may be integrated as one control unit. Alternatively, individual control units may be constituted by a plurality of control units. In addition, the vehicle control system 7000 may include other control units not shown. Further, in the above description, a part or all of the functions of any control unit may be provided in any other control unit. That is, prescribed computation processing may be performed by any control unit, provided that the transmission/reception of information via the communication network 7010 is allowed. Similarly, a sensor or a device connected to any control unit may be connected to any other control unit, and a plurality of control units may transmit/receive detected information to/from each other via the communication network 7010.

Note that it is possible to install a computer program for realizing the respective functions of the light detection device 1 according to the present embodiment described with reference to FIG. 1 or the like in any control unit or the like. Further, it is also possible to provide a computer-readable recording medium storing such a computer program. The recording medium is, for example, a magnetic disc, an optical disc, a magneto-optical disc, a flash memory, or the like. Further, the computer program may be distributed via, for example, a network without a recording medium.

In the vehicle control system 7000 described above, it is possible to apply the light detection device 1 according to the present embodiment described with reference to FIG. 1 or the like to the integrated control unit 7600 of the applied examples shown in FIG. 14.

Further, at least a part of the constituting elements of the light detection device 1 described with reference to FIG. 1 or the like may be realized by a module (for example, an integrated circuit module constituted by one die) for the integrated control unit 7600 shown in FIG. 14. Alternatively, the light detection device 1 described with reference to FIG. 1 may be realized by the plurality of control units of the vehicle control system 7000 shown in FIG. 14.

In view of the above, an embodiment of the present disclosure comprises a light detection device 1 a pixel array having a plurality of pixels 10c. At least one of the plurality of pixels includes a photoelectric conversion region 11 configured to perform photoelectric conversion, a light guide region 14 including first nanostructures 15 that guide light to the photoelectric conversion region 11, and a refraction structure 13 arranged between the light guide region and the photoelectric conversion region and that causes light exiting the light guide region to refract in a refraction direction. In some examples, the at least one pixel further comprises a color filter 12 arranged between the photoelectric conversion region and the refraction structure. In some examples, the refraction structure comprises multiple layers 13a, 13, and the refraction direction is based on (e.g., varies according to) a wavelength of the light exiting the light guide region. In at least one embodiment, the multiple layers includes two or more layers, and the two or more layers have refractive indexes different from each other. For a first pixel of the at least one pixel, the refraction structure comprises a first layer disposed on a first color filter of the first pixel, and for a second pixel of the at least one pixel, the refraction structure includes a second layer disposed on a second color filter of the second pixel. The first layer causes light exiting the light guide region of the first pixel to refract in a first refraction direction, and the second layer does not refract light exiting the light guide region of the second pixel. In some examples, for a first pixel of the at least one pixel, the refraction structure comprises a first layer disposed on a first color filter of the first pixel, and for a second pixel of the at least one pixel, the refraction structure includes a second layer is disposed on a second color filter of the second pixel. Here, the first and second layers may have different refractive indexes. the refraction structure for each pixel of the at least one pixel comprises two or more layers. The light detection device may include a third pixel of the at least one pixel, and the refraction structure 13 comprises a third layer disposed on a third color filter of the third pixel, and the third layer refracts light exiting the light guide region of the third pixel in a second refraction direction. The refraction structure 13 for each of the multiple pixels may cause the multiple pixels to have a same focal distance. In addition, beam diameters at each photoelectric conversion region of each of the multiple pixels may be uniform. In at least one embodiment, the refraction structure for each of the multiple pixels contains a material having a refractive index n so that a focal distance f1 for a first wavelength λ1 is equal to a focal distance f2 for a second wavelength λ2. For each of the multiple pixels, the focal distance is represented by the following formula: f=φ×D×n/(c×λ), where a wavelength of light exiting the light guide region is represented by λ, a refractive index of the refraction structure is represented by n, a beam diameter on a light incident surface of the light guide region is represented by D, a beam diameter on a light receiving surface of the photoelectric conversion region is represented by φ, a focal position of light exiting the refraction structure is represented by f, and a coefficient composed of a prescribed real number is represented by c. In some examples, the refraction structure comprises second nanostructures having a different configuration from the first nanostructures, and the second nanostructures refract light exiting the light guide region. In at least one embodiment, the refraction structure comprises two or more layers and the second nanostructures, each of the two or more layers having refractive indexes different from each other. In addition, a refractive index of the refraction structure for a pixel sensing green light is between a refractive index of the refraction structure for pixels sensing red light and blue light.

Note that the present technology may employ the following configurations.
(1) A light detection device including:
a photoelectric conversion region having a plurality of pixels;
a light control region that is arranged on a light incident direction side with respect to the photoelectric conversion region and has a fine structure to control a propagating direction of incident light; and
a refraction direction adjustment member that is arranged between the light control region and the photoelectric conversion region and adjusts a refraction direction of light emitted from the light control region.
(2) A light detection device including:
a photoelectric conversion region having a plurality of pixels;
a light control region that is arranged on a light incident direction side with respect to the photoelectric conversion region and has a fine structure to control a propagating direction of incident light;
a color filter region that is arranged between the light control region and the photoelectric conversion region; and
a refraction direction adjustment member that is arranged between the light control region and the color filter region and adjusts a refraction direction of light emitted from the light control region.
(3) The light detection device according to (1) or (2), wherein
the refraction direction adjustment member has, for each of the plurality of pixels, a laminated body that adjusts a refraction direction according to a wavelength of incident light.
(4) The light detection device according to (3), wherein
the laminated body of the refraction direction adjustment member includes two or more laminated bodies that correspond to light of two or more wavelengths incident on the light control region, and
the two or more laminated bodies have refractive indexes different from each other.
(5) The light detection device according to (1) or (2), wherein the photoelectric conversion region has a plurality of color pixels for each of the plurality of pixels, and
the refraction direction adjustment member adjusts the refraction direction of the light emitted from the light control region so as to correspond to each of the plurality of color pixels.
(6) The light detection device according to (5), wherein
the light control region has a pixel control region having the fine structure for each of the plurality of color pixels, and
the refraction direction adjustment member adjusts a refraction direction of light emitted from the pixel control region corresponding to at least one color pixel among the plurality of pixel control regions corresponding to the plurality of color pixels.
(7) The light detection device according to (6), wherein
the refraction direction adjustment member makes refraction directions of light emitted from two or more of the pixel control regions among the plurality of pixel control regions corresponding to the plurality of color pixels different from each other, the two or more of the pixel control regions corresponding to the two or more color pixels of different colors.
(8) The light detection device according to (7), wherein
the refraction direction adjustment member has two or more laminated bodies that are arranged in regions on which the light emitted from the two or more pixel control regions is incident, each of the two or more laminated bodies including two or more light transmission layers having refractive indexes different from each other, and
the refractive indexes of one or more of the light transmission layers provided in each of the two or more laminated bodies are different from each other.
(9) The light detection device according to (8), wherein
each of the two or more laminated bodies has
a first light transmission layer having a same refractive index, and
a second light transmission layer that has a different refractive index and is laminated on the first light transmission layer.
(10) The light detection device according to any one of (6) to (9), wherein
the refraction direction adjustment member emits light without changing a refraction direction of the light emitted from the pixel control region corresponding to a color pixel of a specific color among the plurality of color pixels and separately adjusts refraction directions of light emitted from the pixel control regions corresponding to color pixels of colors other than the specific color for each of the colors.
(11) The light detection device according to any one of (6) to (10), wherein
the refraction direction adjustment member adjusts a refraction direction of light emitted from at least a part of the pixel control regions so that focal distances of light emitted from the plurality of pixel control regions corresponding to the plurality of color pixels become uniform.
(12) The light detection device according to (11), wherein
the refraction direction adjustment member adjusts a refraction direction of light emitted from at least a part of the pixel control regions so that beam diameters on the photoelectric conversion region of the light emitted from the plurality of pixel control regions corresponding to the plurality of color pixels become uniform.
(13) The light detection device according to any one of (5) to (12), wherein
the refraction direction adjustment member contains a material having a refractive index n adjusted so that a focal position f expressed by f=φ×D×n/(c×λ) becomes uniform at all wavelengths λ when a wavelength of light emitted from the light control region is represented by λ, a refractive index of the refraction direction adjustment member is represented by n, a beam diameter on a light incident surface of the light control region is represented by D, a beam diameter on a light receiving surface of the photoelectric conversion region is represented by φ, a focal position of light emitted from the refraction direction adjustment member is represented by f, and a coefficient composed of a prescribed real number is represented by c.
(14) The light detection device according to (6), wherein
the refraction direction adjustment member has a separate fine structure having a configuration different from a configuration of the fine structure of the light control region, and
the separate fine structure adjusts a refraction direction of light emitted from at least a part of the pixel control regions and performs pupil correction so that focal distances of light emitted from the plurality of pixel control regions corresponding to the plurality of color pixels become uniform.
(15) The light detection device according to (14), wherein
the refraction direction adjustment member has a laminated body in which two or more light transmission layers having refractive indexes different from each other are laminated and the separate fine structure,
the laminated body is arranged at a place at which no pupil correction is required, and
the separate fine structure is arranged at a place at which pupil correction is required.
(16) The light detection device according to any one of (5) to (15), wherein
the plurality of color pixels have red, green, and blue color pixels, and
the refraction direction adjustment member has
a first region in which light incident on the red color pixels is refracted,
a second region in which light incident on the green color pixels is refracted, and a third region in which light incident on the blue color pixels is refracted, makes a refractive index of the second region larger than a refractive index of the first region, and
makes a refractive index of the third region larger than the refractive index of the second region.
(17) An electronic apparatus including:
a light detection device that outputs a light-detected pixel signal; and
a signal processing section that performs signal processing of the pixel signal, wherein the light detection device includes
a photoelectric conversion region having a plurality of pixels,
a light control region that is arranged on a light incident direction side with respect to the photoelectric conversion region and has a fine structure to control a propagating direction of incident light, and
a refraction direction adjustment member that is arranged between the light control region and the photoelectric conversion region and adjusts a refraction direction of light emitted from the light control region.
(18) A light detection device comprising:
a pixel array having a plurality of pixels, at least one of the plurality of pixels including:
a photoelectric conversion region configured to perform photoelectric conversion;
a light guide region including first nanostructures that guide light to the photoelectric conversion region; and
a refraction structure arranged between the light guide region and the photoelectric conversion region and that causes light exiting the light guide region to refract in a refraction direction.
(19) The light detection device of (18), wherein the at least one pixel further comprises:
a color filter arranged between the photoelectric conversion region and the refraction structure.
(20) The light detection device of one or more of (18) to (19), wherein
the refraction structure comprises multiple layers, and
the refraction direction is based on a wavelength of the light exiting the light guide region.
(21) The light detection device of (20), wherein
the multiple layers includes two or more layers, and
the two or more layers have refractive indexes different from each other.
(22) The light detection device of one or more of (18) to (21), wherein
the refraction direction is based on a wavelength of the light exiting the light guide region.
(23) The light detection device of one or more of (18) to (22), wherein for a first pixel of the at least one pixel, the refraction structure comprises a first layer disposed on a first color filter of the first pixel,
for a second pixel of the at least one pixel, the refraction structure includes a second layer disposed on a second color filter of the second pixel,
the first layer causes light exiting the light guide region of the first pixel to refract in a first refraction direction, and
the second layer does not refract light exiting the light guide region of the second pixel.
(24) The light detection device of one or more of (18) to (23), wherein for a first pixel of the at least one pixel, the refraction structure comprises a first layer disposed on a first color filter of the first pixel,
for a second pixel of the at least one pixel, the refraction structure includes a second layer is disposed on a second color filter of the second pixel, and
the first and second layers have different refractive indexes.
(25) The light detection device of one or more of (18) to (24), wherein
the refraction structure for each pixel of the at least one pixel comprises two or more layers.
(26) The light detection device of (25), wherein each of the two or more layers comprises:
a first layer having a first refractive index; and
a second layer on the first layer and having a second refractive index which is different from the first refractive index.
(27) The light detection device of one or more of (18) to (26), wherein for a third pixel of the at least one pixel, the refraction structure comprises a third layer,
the third layer is disposed on a third color filter of the third pixel, and
the third layer refracts light exiting the light guide region of the third pixel in a second refraction direction.
(28) The light detection device of one or more of (18) to (27), wherein
the at least one pixel include multiple pixels, and
the refraction structure for each of the multiple pixels causes the multiple pixels to have a same focal distance.
(29) The light detection device of (28), wherein
beam diameters at each photoelectric conversion region of each of the multiple pixels are uniform.
(30) The light detection device of one or more of (28) to (29), wherein
the refraction structure for each of the multiple pixels contains a material having a refractive index n so that a focal distance f1 for a first wavelength λ1 is equal to a focal distance f2 for a second wavelength λ2,
wherein, for each of the multiple pixels:
the focal distance is represented by the following formula:

f=φ×D×n/(c×λ),

where a wavelength of light exiting the light guide region is represented by λ, a refractive index of the refraction structure is represented by n, a beam diameter on a light incident surface of the light guide region is represented by D, a beam diameter on a light receiving surface of the photoelectric conversion region is represented by φ, a focal position of light exiting the refraction structure is represented by f, and a coefficient composed of a prescribed real number is represented by c.
(31) The light detection device of one or more of (18) to (30), wherein
the refraction structure comprises second nanostructures having a different configuration from the first nanostructures, and
the second nanostructures refract light exiting the light guide region.
(32) The light detection device of (31), wherein
the refraction structure comprises two or more layers and the second nanostructures, each of the two or more layers having refractive indexes different from each other.
(33) The light detection device of one or more of (18) to (32), wherein
the wavelength of light corresponds to red light, green light, or blue light, and a refractive index of the refraction structure for green light is between a refractive index of the refraction structure for red light and blue light.
(34) An electronic apparatus comprising:
a light detection device that outputs a light-detected pixel signal; and
a signal processing section that performs signal processing of the pixel signal, wherein the light detection device includes:
a pixel array having a plurality of pixels, at least one of the plurality of pixels including:
a photoelectric conversion region configured to perform photoelectric conversion;
a light guide region including first nanostructures that guide light to the photoelectric conversion region; and
a refraction structure arranged between the light guide region and the photoelectric conversion region and that causes light exiting the light guide region to refract in a refraction direction.
(35) A light detection device comprising:
a plurality of pixels, each of the plurality of pixels including:
a photoelectric conversion region configured to perform photoelectric conversion;
a light guide region including first nanostructures that guide light to the photoelectric conversion region; and
a refraction structure that causes light exiting the light guide region to refract in a refraction direction.
(36) The light detection device of one or more of (35), wherein
the refraction structure comprises multiple layers, and
the multiple layers have refractive indexes different from each other.
(37) The light detection device of one or more of (35) to (36), wherein
for a first pixel of the plurality of pixels, the refraction structure includes a first layer disposed on a first color filter of the first pixel,
for a second pixel of the plurality of pixels, the refraction structure includes a second layer disposed on a second color filter of the second pixel,
the first and second color filters pass different wavelengths of light, and
the first and second layers have different refractive indexes.

The mode of the present disclosure is not limited to the above individual embodiments but includes various modifications that could be conceived by persons skilled in the art. The effect of the present disclosure is not limited to the above contents. That is, it is possible to perform various addition, change, and partial deletion without departing from the conceptual idea and gist of the present disclosure derived from the contents stipulated in claims and their equivalents.

### REFERENCE SIGNS LIST

1 Light detection device
2 Pixel array unit
3 Vertical driving circuit
4 Column signal processing circuit
5 Horizontal driving circuit
6 Output circuit
7 Control circuit
10 Adjacent pixel unit
10 Pixel unit
10b Blue pixel
10b Color pixel
10c Color pixel
10g Color pixel
10g Green pixel
10r Red pixel
10r Color pixel
11 Photoelectric conversion region
12 Color filter region
12b Color filter part
12c Color filter part
12g Color filter part
12r Color filter part
13 Refraction direction adjustment member (Refraction structure)
13a First light transmission layer
13b Second light transmission layer
14 Light control region (Light guide region)
14 Color splitter
15 Fine structure
15b Base member
15p Pillar part
16 Pixel control region (Pixel light guide region)
17 Anti-reflection layer
18 Insulating layer
20 Opening range
100 Light detection device

What is claimed is:

1. A light detection device, comprising:
a pixel array having a plurality of pixels, at least one of the plurality of pixels including:
a photoelectric conversion region configured to perform photoelectric conversion;
a light guide region including first nanostructures that guide light to the photoelectric conversion region; and
a refraction structure arranged between the light guide region and the photoelectric conversion region and that causes light exiting the light guide region to refract in a refraction direction.

2. The light detection device according to claim 1, wherein the at least one pixel further comprises:
a color filter arranged between the photoelectric conversion region and the refraction structure.

3. The light detection device according to claim 1, wherein
the refraction structure comprises multiple layers, and
the refraction direction is based on a wavelength of the light exiting the light guide region.

4. The light detection device according to claim 3, wherein
the multiple layers includes two or more layers, and
the two or more layers have refractive indexes different from each other.

5. The light detection device according to claim 2, wherein
the refraction direction is based on a wavelength of the light exiting the light guide region.

6. The light detection device according to claim 1, wherein
for a first pixel of the at least one pixel, the refraction structure comprises a first layer disposed on a first color filter of the first pixel,
for a second pixel of the at least one pixel, the refraction structure includes a second layer disposed on a second color filter of the second pixel,
the first layer causes light exiting the light guide region of the first pixel to refract in a first refraction direction, and
the second layer does not refract light exiting the light guide region of the second pixel.

7. The light detection device according to claim 1, wherein
for a first pixel of the at least one pixel, the refraction structure comprises a first layer disposed on a first color filter of the first pixel,
for a second pixel of the at least one pixel, the refraction structure includes a second layer is disposed on a second color filter of the second pixel, and
the first and second layers have different refractive indexes.

8. The light detection device according to claim 1, wherein
the refraction structure for each pixel of the at least one pixel comprises two or more layers.

9. The light detection device according to claim 8, wherein each of the two or more layers comprises:
a first layer having a first refractive index; and
a second layer on the first layer and having a second refractive index which is different from the first refractive index.

10. The light detection device according to claim 6, wherein
for a third pixel of the at least one pixel, the refraction structure comprises a third layer,
the third layer is disposed on a third color filter of the third pixel, and
the third layer refracts light exiting the light guide region of the third pixel in a second refraction direction.

11. The light detection device according to claim 1, wherein
the at least one pixel include multiple pixels, and
the refraction structure for each of the multiple pixels causes the multiple pixels to have a same focal distance.

12. The light detection device according to claim 11, wherein
beam diameters at each photoelectric conversion region of each of the multiple pixels are uniform.

13. The light detection device according to claim 11, wherein
the refraction structure for each of the multiple pixels contains a material having a refractive index n so that a focal distance f1 for a first wavelength λ1 is equal to a focal distance f2 for a second wavelength λ2,
wherein, for each of the multiple pixels:
the focal distance is represented by the following formula:
f=φ×D×n/(c×λ),
where a wavelength of light exiting the light guide region is represented by λ, a refractive index of the refraction structure is represented by n, a beam diameter on a light incident surface of the light guide region is represented by D, a beam diameter on a light receiving surface of the photoelectric conversion region is represented by φ, a focal position of light exiting the refraction structure is represented by f, and a coefficient composed of a prescribed real number is represented by c.

14. The light detection device according to claim 1, wherein
the refraction structure comprises second nanostructures having a different configuration from the first nanostructures, and
the second nanostructure refracts light exiting the light guide region.

15. The light detection device according to claim 14, wherein
the refraction structure comprises two or more layers and the second nanostructures, each of the two or more layers having refractive indexes different from each other.

16. The light detection device according to claim 5, wherein
the wavelength of light corresponds to red light, green light, or blue light, and a refractive index of the refraction structure for green light is between a refractive index of the refraction structure for red light and blue light.

17. An electronic apparatus, comprising:
a light detection device that outputs a light-detected pixel signal; and
a signal processing section that performs signal processing of the pixel signal, wherein the light detection device includes:
a pixel array having a plurality of pixels, at least one of the plurality of pixels including:
a photoelectric conversion region configured to perform photoelectric conversion;
a light guide region including first nanostructures that guide light to the photoelectric conversion region; and
a refraction structure arranged between the light guide region and the photoelectric conversion region and that causes light exiting the light guide region to refract in a refraction direction.

18. A light detection device, comprising:
a plurality of pixels, each of the plurality of pixels including:
a photoelectric conversion region configured to perform photoelectric conversion;
a light guide region including first nanostructures that guide light to the photoelectric conversion region; and
a refraction structure that causes light exiting the light guide region to refract in a refraction direction.

19. The light detection device according to claim 18, wherein
the refraction structure comprises multiple layers, and
the multiple layers have refractive indexes different from each other.

20. The light detection device according to claim 18, wherein
for a first pixel of the plurality of pixels, the refraction structure includes a first layer disposed on a first color filter of the first pixel,
for a second pixel of the plurality of pixels, the refraction structure includes a second layer disposed on a second color filter of the second pixel,
the first and second color filters pass different wavelengths of light, and
the first and second layers have different refractive indexes.
